(19) United States
(12) Patent Application Publication
(10) Pub. No.: US 2025/0377398 A1
(43) Pub. Date: Dec. 11, 2025

(54) COMPARATIVE DEVICE OPERATING TEMPERATURE ANOMALY DETECTION

(71) Applicant: Inventus Holdings, LLC, Juno Beach, FL (US)

(72) Inventors: Kelsa B ANDERSON, Palm Beach Gardens, FL (US); Saman TAHERI, Palm Beach Gardens, FL (US)

(21) Appl. No.: 18/739,853

(22) Filed: Jun. 11, 2024

(51) Int. Cl. G01R 31/26; G01K 3/00

(52) U.S. Cl. CPC G01R 31/2619; G01K 3/005

(57) ABSTRACT

Systems and methods for determining an abnormality of a semiconductor switch. A baseline temperature of semiconductor switches within a particular operating electronic device is determined based on measured temperatures of semiconductor switches within at least one operating electronic device. Measurements of a respective temperature value of each semiconductor switch in a plurality of semiconductor switches within the particular operating electronic device is received. An overheating semiconductor switch within the plurality of semiconductor switches is determined based on a determination that the respective temperature value of the overheating semiconductor switch is higher than the baseline temperature by at least a threshold. An abnormal condition for the overheating semiconductor switch is indicated based on determining that an operating temperature of a particular semiconductor switch deviates from the baseline by at least a threshold.

### FIELD OF THE DISCLOSURE

The present disclosure generally relates to monitoring operating systems, and more particularly to detecting anomalies based upon operating temperature of different operating semiconductor devices.

### BACKGROUND

Power electronic devices, especially those used in utility scale applications, incorporate semiconductor switches that control high electrical current levels. Such devices, particularly semiconductor switches, often operate under harsh conditions that lead to failures of the semiconductor switches.

Some power electronic devices, such as three phase AC power converters, use a number of high power semiconductor switches such as Insulated Gate Bipolar Transistor (IGBT) semiconductor switches in a bridge or array arrangement. In some instances, an electronic power device may have a failure of just one IGBT semiconductor switch during operations, but the failure of that one IGBT semiconductor switch may result in fairly severe further damage to other components of that electronic power device.

### BRIEF DESCRIPTION OF THE DRAWINGS

The accompanying figures where like reference numerals refer to identical or functionally similar elements throughout the separate views, and which together with the detailed description below are incorporated in and form part of the specification, serve to further illustrate various embodiments and to explain various principles and advantages all in accordance with the present disclosure, in which:

FIG. 1 illustrates a schematic of a wind turbine with power converter 100, according to an example;

FIG. 2 illustrates a partial power converter schematic 200, according to an example;

FIG. 3 illustrates a data collection and processing system 300, according to an example;

FIG. 4 illustrates an intra-device abnormality detection process 400, according to an example;

FIG. 5 illustrates a baseline temperature function determination process 500, according to an example;

FIG. 6 illustrates an inter-device abnormality detection process 600, according to an example, and

FIG. 7 illustrates a block diagram illustrating a processor, according to an example.

### DETAILED DESCRIPTION

As required, detailed embodiments are disclosed herein; however, it is to be understood that the disclosed embodiments are merely examples and that the systems and methods described below can be embodied in various forms. Therefore, specific structural and functional details disclosed herein are not to be interpreted as limiting, but merely as a basis for the claims and as a representative basis for teaching one skilled in the art to variously employ the disclosed subject matter in virtually any appropriately detailed structure and function. Further, the terms and phrases used herein are not intended to be limiting, but rather, to provide an understandable description.

The terms “a” or “an”, as used herein, are defined as one or more than one. The term plurality, as used herein, is defined as two or more than two. The term another, as used herein, is defined as at least a second or more. The terms “including” and “having,” as used herein, are defined as comprising (i.e., open language). The term “coupled,” as used herein, is defined as “connected,” although not necessarily directly, and not necessarily mechanically. The term "configured to" describes hardware, software or a combination of hardware and software that is adapted to, set up, arranged, built, composed, constructed, designed or that has any combination of these characteristics to carry out a given function. The term "adapted to" describes hardware, software or a combination of hardware and software that is capable of, able to accommodate, to make, or that is suitable to carry out a given function.

The below described systems and method operate to monitor the operations of electronic devices, including but not limited to electronic power devices, in order to monitor the operations of power semiconductor devices, such as semiconductor switches, within the electronic power devices in order to determine likely upcoming failures. In an example, the electronic power devices being monitored include a number of semiconductor switches arranged in a bridge configuration and the temperature of each semiconductor switch is monitored while the electronic power device is operating.

It has been observed that semiconductor switches in good operating condition in an operating electronic device will have consistent baseline temperatures for a given set of operating conditions. Examples of various operating conditions include, without limitation, one or more of real electrical power, reactive electrical power, electrical voltage, electrical current, power factor, ambient temperature, or combinations of these. It has been further observed that as a semiconductor switch degrades and is likely to fail in the near future, it will exhibit an operating temperature that is higher than the baseline temperature given that device’s operating conditions. The below systems and methods operate to monitor semiconductor switches of operating electronic devices in order determine when a semiconductor switch is exhibiting a higher than baseline temperature in order to warn of an upcoming failure of that semiconductor switch so that preventative measures can be taken such as replacement of that semiconductor switch before it fails and potentially cause further damage to the electronic device in which it is operating.

The operation of the below described systems and methods to detect degraded operations of semiconductor switches, such as Insulated Gate Bipolar Transistors (IGBTs), and allows maintenance actions to be performed on the electronic device prior to a failure of that semiconductor switch. For example, a degraded IGBT device could be replaced prior to its outright failure, obviating the extensive damage to the electronic device that often accompanies the outright failure of an operating IGBT.

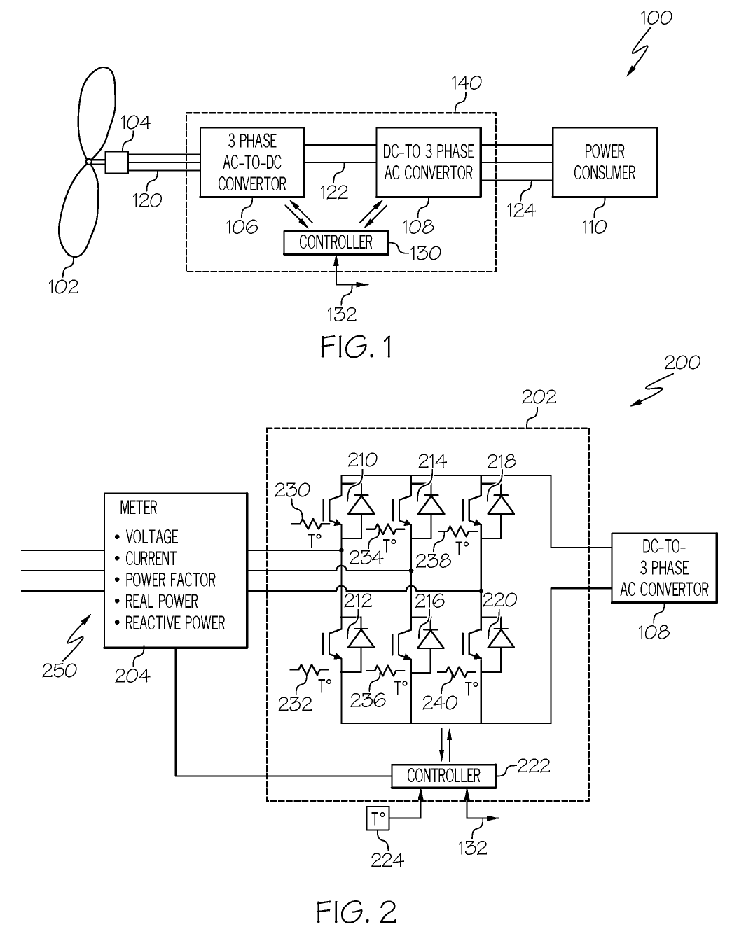

FIG. 1 illustrates a schematic of a wind turbine with power converter 100, according to an example. The wind turbine with power converter 100 depicts a wind turbine blade assembly 102 that drives a three-phase power generator 104. The electrical power level and AC frequency provided by the three-phase power generator 104 can vary due to the speed of the wind driving the wind turbine blade assembly 102. The electrical power generated by the three-phase power generator 104 is provided to a three-phase electrical power converter 140. The illustrated three-phase electrical power converter 140 is an example of an electronic power device with a number of semiconductor switches. The below described systems and methods operate to monitor the semiconductor switches in the electronic power device while it is operating to determine anomalous conditions such as conditions that indicate a likely upcoming failure of one or more of those semiconductor switches.

The three-phase electrical power converter 140 includes a three-phase AC to DC converter 106 and a DC to three-phase AC converter 108. The three-phase AC to DC converter 106 receives three-phase AC electrical power and converts it to DC power provided to a DC connector bus 122. The DC to three-phase AC converter 108 receives DC power from the DC connector bus 122 and provides it on a three-phase AC output port 124 to a consumer of the power, to a grid connection, or combinations of these. In an example, the DC to three-phase AC converter 108 has a similar circuit design as the three-phase AC to DC converter 106. In some examples the three-phase AC to DC converter 106 and DC to three-phase AC converter 108 each contain six (6) semiconductor switches. In some examples, the semiconductor switches are Insulated Gate Bipolar Transistor (IGBT) devices.

In an example, a controller 130 in the three-phase electrical power converter 140 controls and monitors the operations of the semiconductor switches that process the electrical power passing through the three-phase electrical power converter 140. In an example, the controller 130 operates to control the switching of the semiconductor switches in the three-phase electrical power converter 140 and monitors temperature sensors associated with each semiconductor switch.

The controller 130 in an example communicates with external systems over a communications channel 132. The communications channel 132 in an example communicates commands to be received by the controller 130 to control operations of the three-phase electrical power converter 140 and also communicates status reports generated and sent by the controller 130. In some examples, the controller 130 creates and sends status messages that include various data such as, but not limited to, measured values of the temperature of each semiconductor switch in the three-phase electrical power converter 140, values associated with operating conditions of the three-phase electrical power converter 140, indications of determined anomalous conditions such as overheating semiconductor switches, other data, or combinations of these.

In an example, the controller 130 receives measured temperatures of the semiconductor switches while the three-phase electrical power converter 140 is operating. The controller 130 in various examples compares the temperature of each operating semiconductor switch to a baseline temperature of semiconductor switches to determine an overheating semiconductor switch and indicate an anomalous condition that is likely to precede failure of that overheating semiconductor switch. The baseline temperature is able to be determined by any suitable technique including examples described below.

In one example, the controller 130 monitors temperatures of all of the semiconductor switches in an operating three-phase electrical power converter 140 and uses those values, which in an example are collected within a defined time duration, as a baseline temperature to determine if the temperature of one operating semiconductor switch exceeds the temperature of other operating semiconductor switches by a threshold. The defined time duration in various examples is able to be determined as a time duration over which the temperatures of semiconductor switches is unlikely to appreciably change. Such time durations are able to consider the heat capacities of semiconductor switch cooling structures, empirical data regarding temperature changes, other factors, or combinations of these.

In another example, the controller 130 is able to determine or receive data to determine a baseline temperature value that is dependent upon the operating conditions of the three-phase electrical power converter 140. The controller 130 in such an example determines the present operating conditions for the three-phase electrical power converter 140 such as by receiving measurements made by equipment in the three-phase electrical power converter 140 or by information received from other sources. In some examples, the controller receives a definition of a baseline semiconductor switch temperature function and is able to semiconductor switches by evaluating that function for the determined values of the operating conditions of the three-phase electrical power converter. The controller 130 in that example determines an overheating semiconductor switch by comparing the determined baseline temperature associated with the determined operating conditions to the measured temperatures of the semiconductor switches in the three-phase electrical power converter 140. In an example, baseline temperature values, data indicating values associated with the operating conditions of the three-phase electrical power converter 140, other data, or combinations of these, are able to be received via the communications channel 132.

In yet further examples, the controller 130 is able to communicate one or more of measured temperatures of the semiconductor switches, measured values associated with the operating condition of the three-phase electrical power converter 140, or combinations of these, to a remote processor via communications channel 132. An example of such a remote processor is described below that is able to receive and process the data sent by the controller 130 to determine anomalous conditions such as an overtemperature semiconductor switch.

FIG. 2 illustrates a partial power converter schematic 200, according to an example. The partial power converter schematic 200 depicts a simplified circuit 202 that illustrates components that are included in a three-phase to DC converter 106 that is described above. In some examples, components in the DC to three-phase AC converter 108 are similar to the simplified circuit 202 and its operation can be similar with regards to the status reporting described below. The partial power converter schematic 200 depicts a controller 222 that controls the operations of the partial power converter schematic 200. The controller 222 is an example of the above described controller 130.

The partial power converter schematic 200 includes an ambient temperature meter 224. The ambient temperature meter 224 is configured to measure temperatures near the simplified circuit 202 in order to support accurate determination of a temperature baseline for given ambient temperatures of the semiconductor switches in the simplified circuit 202. The ambient temperature meter 224 is able to include one or more temperature monitors that is able to be mounted in any location used to support baseline temperature determination such as on or near a case of a device containing the simplified circuit 202, in a cabinet containing that device, in other areas, or in any combination of these.

The partial power converter schematic 200 receives three-phase AC electrical power via a three-phase electrical line 250. The three-phase electrical line 250 is connected to a meter 204 that measures various electrical quantities being processed by the simplified circuit 202. In various examples, the meter 204 measures one or more of electrical voltage delivered to the simplified circuit 202, electrical current delivered to the simplified circuit 202, the power factor of the voltage and current delivered to the simplified circuit 202, other measurements, or combinations of these. In some examples, the meter 204 is also able to produce measurements for real power and reactive power. Real power and reactive power levels are able to be determined in an example based on measured levels of voltage, current, and the angle between those values which corresponds to the power factor of the electrical energy measured by the meter 204.

The meter 204 has a three-phase power meter output 252 that provides three-phase AC power to the simplified circuit 202. The simplified circuit 202 provides a DC output on a DC interface 260. The DC interface 260 in this example corresponds to the DC connector bus 122 described above. In the illustrated example, semiconductor switches within the simplified circuit 202 switch connections between the three (3) lines of the three-phase power meter output 252 and the two lines of the DC interface 260 to convert the received three-phase AC input power to DC output power.

The simplified circuit 202 implements a switching matrix with six (6) semiconductor switches. In an example, these semiconductor switches are Insulated Gate Bipolar Transistors (IGBTs) but the illustrated principles are able to be applied to any design. A controller 222 controls these six (6) semiconductor switches to open and close in synchronization with the AC power cycles on the three-phase power meter output 252. The controller 222 operates to open switches between each AC line and the DC positive line 262 and close switches between the AC lines and the DC negative line 264 when the voltage on each of those AC lines is positive. The controller 222 also operates to open switches between each AC line and the DC negative line 264, and close switches between the AC lines and the DC positive line 262 when the voltage on each of those AC lines is negative. Such operations allow the simplified circuit 202 to convert the three-phase AC power to DC power.

The disclosed systems and methods monitor the operation of the semiconductor switches to identify anomalous conditions in order to, for example, provide indications of possible upcoming failures of a semiconductor switch. In an example, the temperature of each semiconductor switch is measured and compared to a baseline temperature. The baseline temperature in some examples is a function of operating conditions of the simplified circuit 202, which in some examples corresponds to or can be related to the operating conditions of an electronic device containing the simplified circuit 202.

Each semiconductor switch in the simplified circuit 202 has an associated temperature sensor to monitor the present temperature of each operating semiconductor switch. For example, the first semiconductor switch 210 has a first temperature sensor 230, the second semiconductor switch 212 has a second temperature sensor 232, the third semiconductor switch 214 has a third temperature sensor 234, the fourth semiconductor switch 216 has a fourth temperature sensor 236, the fifth semiconductor switch 218 has a fifth temperature sensor 238, and the sixth semiconductor switch 220 has a sixth temperature sensor 240. Each of these temperature sensors is configured to measure a present temperature of its associated semiconductor switch.

The controller 222 of the simplified circuit 202 in an example is connected to each of these temperature sensors and receives an individual measurement of the present temperature of each semiconductor switch. In an example, the controller 222 also receives the measurements made by the meter 204 of quantities associated with the power processed by the simplified circuit 202. The controller 222 also receives ambient temperature measurements from an ambient temperature meter 224 that is in the vicinity of the simplified circuit 202.

The controller 222 in the illustrated example communicates data via a communications channel 132 as is described above. In some examples, the controller 222 is able to perform processing to determine overheating semiconductor switches without external communications. In further examples, the controller 222 receives data, such as one or more of baseline temperatures of semiconductor switches as a function of operating conditions, ambient data such as an environmental temperature measured by a remote system, other data, or combinations of these, and use such data in processes to determine anomalous conditions such as overheating semiconductor switches. The controller is able to, in some examples, communicate indications of an abnormal condition such as an overheating semiconductor switch. In various examples, the controller 222 is able to provide indications of such abnormal condition by any technique.

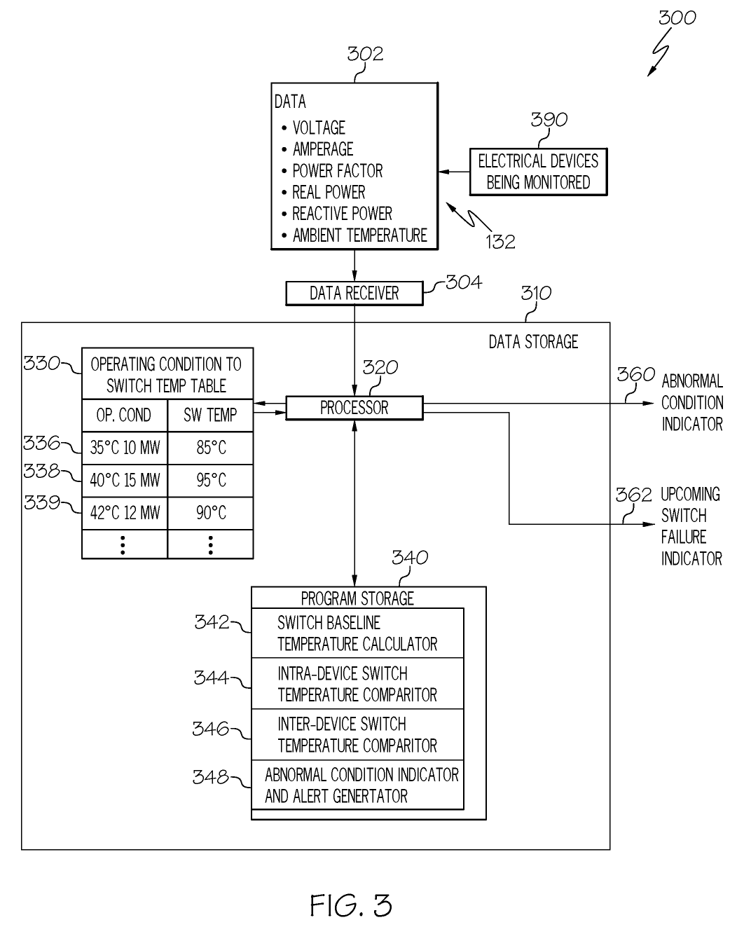

FIG. 3 illustrates a data collection and processing system 300, according to an example. The data collection and processing system 300 is an example of a processing system that is able to be utilized in realizing the systems and methods described herein. The data collection and processing system 300 is an example of a system that is able to receive data collected and sent by the above described controller 130 or controller 222 to determine abnormal conditions based on determining overheating semiconductor switches.

The data collection and processing system 300 includes an electronic device monitoring processor 310 that receives data 302 via a data receiver 304. The electronic device monitoring processor 310 processes the received data to detect and determine the existence of an anomalous condition within a monitored electronic device and provide indications of such detected anomalous conditions. In an example the electronic device monitoring processor 310 determines anomalous conditions that indicate a likelihood of an upcoming failure of a semiconductor switch in an electronic device monitored by the data collection and processing system 300.

The data receiver 304 in the illustrated example is connected to the above described communications channel 132 and has data communications with one or more electrical devices being monitored 390. The electrical devices being monitored 390 in an example include one or more three-phase electrical power converters 140 or other electrical power devices. The processing of the data collection and processing system 300 in an example operates to detect anomalous conditions, such as an abnormally elevated temperature of one or more semiconductor switches in one or more three-phase electrical power converter 140 that indicates a likelihood of upcoming failure of that semiconductor power device.

The data collection and processing system 300 receives and processes data from one or more operating electronic devices that each contains a number of semiconductor switches. In an example, such semiconductor switches are able to include Insulated Gate Bipolar Transistors (IGBTs). It has been observed that in normal operations, IGBT semiconductor switches in electronic power devices generally operate at relatively consistent operating temperatures that are a function of certain operating condition values for the electrical power device in which the semiconductor switches are operating.

In an example, the received data 302 includes measured values of quantities associated with the operating conditions of the electrical power converter that have been noted to affect the temperature of operating semiconductor devices. It has been observed that the operating temperature of semiconductor switches are functions of quantities such as electrical current, voltage and power factor, real electrical power and reactive electrical power. Values of measured operating conditions that are included in the data 302 in an example include, but are not limited to, quantities such as: the line voltages feeding the particular operating electronic power device; electrical current flowing through the particular operating electronic power device; electrical power factor of power flowing through the particular operating electronic power device; the ambient temperature of the particular operating electronic power device; real electrical power; reactive electrical power; or combinations of these.

In some examples, the received data 302 includes measured operating temperatures of each semiconductor switch in a reporting electrical power device. Such data in some examples is able to provide an identifier of the electronic device for which the data pertains and in some examples the data 302 is able to include an identifier of each semiconductor switch along with its operating temperature. In further examples, the data does not include an identification of the particular semiconductor switches and only provides the operating temperatures of those semiconductor switches. Such operating temperature data associated with operating conditions is able to be used to accumulate data to determine baseline temperatures as a function of operating conditions and also is able to be used to identify a particular electronic power device that has an overheating semiconductor switch even though the particular semiconductor switch is not identified in the received data 302.

The electronic device monitoring processor 310 includes a processor 320. The processor 320 has access to an operating condition versus semiconductor device temperature table 330 and a program storage 340. The processor 320 in various examples is able to perform various operations including processing to support monitoring of the electronic devices being monitored. For example, that processes data within the operating condition versus semiconductor device temperature table 330 to produce baseline temperature of semiconductor switches within a particular operating electronic power device.

The processor 320 of the electronic device monitoring processor 310 receives the data 302 and stores it in the operating condition versus semiconductor device temperature table 330. The operating condition versus semiconductor device temperature table 330 includes a column for operating conditions values 332 and a column for switch temperature 334. Each row of the operating condition versus semiconductor device temperature table 330 has an observed switch temperature in the column for switch temperature 334 and measured values of quantities reflecting the operating condition associated with that temperature measurement.

The illustrated operating condition versus semiconductor device temperature table 330 depicts three (2) rows of data and ellipses to depict an arbitrary number of additional rows. Each row of data includes a specification of operating condition values 332 and a semiconductor switch temperature 334 that was measured under the associated operating condition values 332 in that row. A first row 336 depicts operating condition values of 35 ºC as the ambient temperature of the electrical power device and 10 MW (MegaWatts) of real power being processed by the electrical power device. The first row 336 also contains a corresponding semiconductor switch temperature of 85 ºC that was measured under those operating conditions. The second row 338 depicts operating condition values of 40 ºC as the ambient temperature and 15 MW of real power, with a corresponding semiconductor switch temperature of 95 ºC that was measured under those operating conditions. A third row 339 depicts operating condition values of 42 ºC as ambient temperature and 12 MW real power with a corresponding semiconductor switch temperature of 90 ºC that was measured under those operating conditions.

The illustrated example uses ambient temperature and real electrical power as operating condition values with which operating semiconductor switch temperatures are correlated. In various examples, each value of measured switch temperature in the received data 302 is able to have measurements of any number of various associated operating condition values. For example, the data 302 is able to contain a data set received from an operating electrical power device within the electrical devices being monitored 390 that contains the values of the measured temperature of each semiconductor switch in the operating electrical power device along with some or all of measured data values such as: voltage across the device; electrical current passing through the device, the power factor of the power passing through the device, ambient temperature, other values, or combination of these. In some examples, the received dataset is able to contain a value of just one of these operating condition quantities, or values of any number of these operating condition quantities.

The program storage 340 in an example contains a number of programs that are executable by the processor 320 to perform various tasks. The illustrated program storage 340 includes a switch temperature baseline calculator 342, an intra-device switch temperature comparison process 344, an inter-switch temperature comparison process 346, and an abnormal condition indication generator 348.

The switch temperature baseline calculator 342 receives measured temperatures of operating semiconductor switches within an operating electronic power device along with data describing operating conditions of the operating electronic power device at the time of the measurement. The switch temperature baseline calculator 342 in an example determines values of baseline temperatures for semiconductor switches as a function of values of operating conditions. Any technique is able to be used to calculate a baseline temperature as a function of values of quantities associated with operating conditions, such as a linear regression or least squares curve fitting process, a look up table that returns values of temperatures that correspond to stored values of operating conditions that are closest to the operating conditions being supplied for determining a corresponding switch temperature baseline, other techniques, or combinations of these. Any such process is an example of determining the baseline temperature of semiconductor switches based on the baseline semiconductor switch temperature function evaluated at the measurements of values of at least one operating condition value of the particular operating electronic device.

In an example, the switch temperature baseline calculator is able to accumulate different combinations of operating condition values so that baseline temperatures are able to be determined for any one or more operating condition value. In an example, the switch temperature baseline calculator 342 is able to be configured to accumulate a particular combination of operating condition values, such as ambient temperature and real power, and calculate baseline temperatures for semiconductor switches based on those values.

The intra-device switch temperature comparison process 344 in an example operates to compare the measured operating temperatures of operating semiconductor switches in one particular electronic power device in order to determine if a measured temperature of one semiconductor switch exceeds the operating temperature of the other semiconductor switches in that same electronic power device. In some examples, a determination of an anomalous condition in which a semiconductor switch is about to fail is able to be based on determining that the operating temperature of one semiconductor switch exceeds the operating temperatures of other semiconductor switches in the same electronic power device by a threshold. Such a determination is able to be made independent of operating condition values for the electronic power device.

The inter-switch temperature comparison process 346 in an example operates to compare the measured operating temperatures of operating semiconductor switches to a baseline temperature of operating semiconductor switches in an operating power electronic device given the values of particular operating conditions. Such a comparison is used to determine if a measured temperature of one semiconductor switch exceeds that baseline temperature by a threshold, which is a basis of determining an anomalous condition that is an indicator of an upcoming failure of that semiconductor switch.

The abnormal condition indication generator 348 in an example receives determinations of abnormal conditions detected by other processes, such as the above described intra-device switch temperature comparison process 344 or the inter-switch temperature comparison process 346. Based on receipt of these received determinations, the abnormal condition indication generator 348 in an example causes the processor 320 to produce an output such as an abnormal condition indicator 360 or the upcoming switch failure indicator 362.

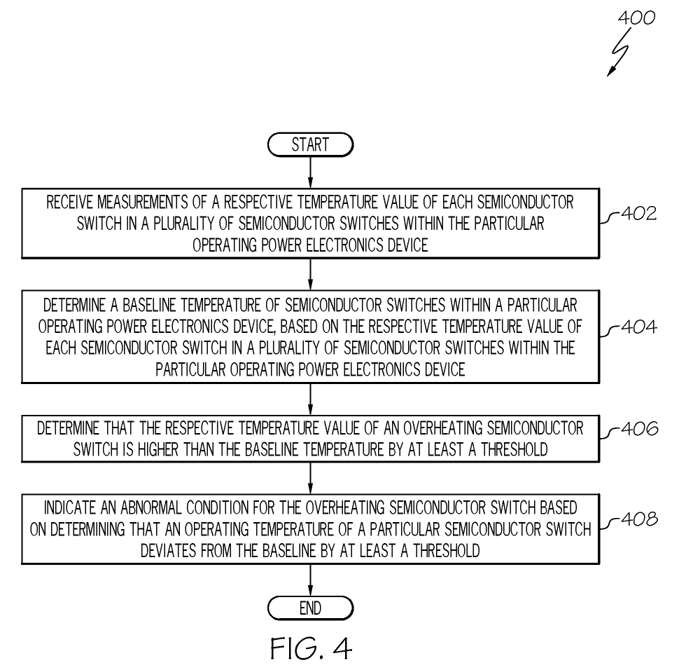

FIG. 4 illustrates an intra-device abnormality detection process 400, according to an example. The intra-device abnormality detection process 400 is an example of a process that monitors quantities associated with a single operating electronic power device to detect potentially anomalous conditions that could indicate a potential upcoming failure of a semiconductor switch in that electronic power device. The intra-device abnormality detection process 400 is an example of processing performed by a controller of an electronic power device, such as the above described controller 130 or controller 222, operating to process measured temperature data of operating semiconductor switches within its three-phase electrical power converter 140 or the simplified circuit 202. In some examples, the intra-device abnormality detection process 400 is an example of processing performed by the above described processor 320 in the electronic device monitoring processor 310 when executing the intra-device switch temperature comparison process 344 to process temperature data reported for a particular electronic power device.

The intra-device abnormality detection process 400 receives, at 402, measurements of a respective temperature value of each semiconductor switch in a plurality of semiconductor switches within the particular operating electronic power device. In an example, such measurements are received from temperature sensors installed in association with each semiconductor switch and are reported to a controller within the electronic power device.

The intra-device abnormality detection process 400 determines, at 404, a baseline temperature of semiconductor switches within a particular operating electronic power device, based on the respective temperature value of each semiconductor switch in a plurality of semiconductor switches within the particular operating electronic power device. In an example, the baseline temperature is able to determined based on the measured temperature of operating power semiconductor devices that are within a range of each other. In some examples the baseline temperature is determined based on evaluation of the baseline semiconductor switch temperature function at the measured values of at least one operating condition value of the particular operating electronic device.

The intra-device abnormality detection process 400 determines, at 406, that the respective temperature value of an overheating semiconductor switch is higher than the baseline temperature by at least a threshold. In an example, this determination is based on determining that at least one operating semiconductor switch has a temperature greater than other operating semiconductor switches in the same electronic power device.

The intra-device abnormality detection process 400 indicates, at 408, an abnormal condition for the overheating semiconductor switch based on determining that an operating temperature of a particular semiconductor switch deviates from the baseline by at least a threshold. This indication is able to be provided by any suitable technique. For example, a data message may be sent to service personnel indicating the abnormal condition as an indication of an upcoming possible failure of the overheating semiconductor switch.

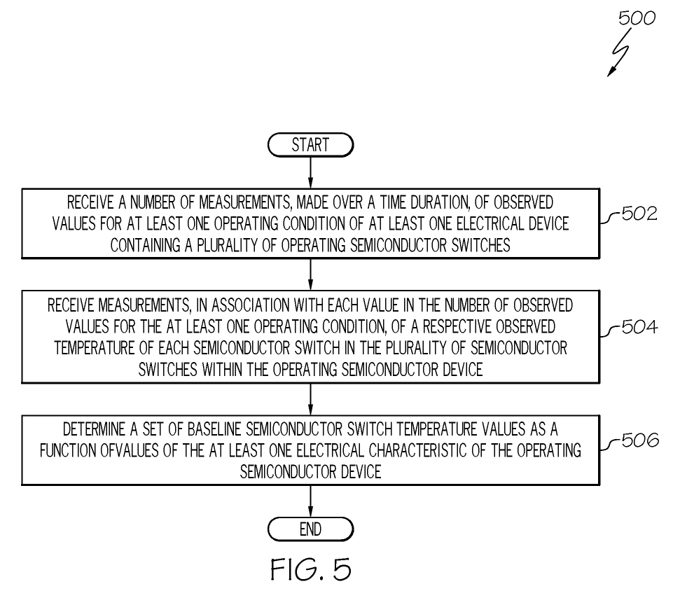

FIG. 5 illustrates a baseline temperature function determination process 500, according to an example. The baseline temperature function determination process 500 is an example of a process performed by the above described processor 320 when executing the switch baseline temperature calculator 342. In some examples, the baseline temperature function determination process 500 is able to operate on a controller, such as controller 222 of the above simplified circuit 202, to process semiconductor switch temperature data from a single electronic power device.

The baseline temperature function determination process 500 receives, at 502, a number of measurements, made over a time duration, of observed values for at least one operating condition of at least one electrical device containing a plurality of operating semiconductor switches. In an example, such measurements are received at an electronic device monitoring processor 310 from a controller, such as controller 222, after receiving such measurements from monitors, such as meter 204 or ambient temperature sensor 324. In some examples, such measurements of observed values are able to be measured by, and sent from, any suitable equipment. In various examples, a time duration over which such measurements are made is able to be defined as a time over which the operating temperatures are not likely to appreciably change. Such time durations are able to consider the heat capacities of semiconductor switch cooling structures, empirical data regarding temperature changes, other factors, or combinations of these.

The baseline temperature function determination process 500 receives, at 504 in association with each value in the number of measurements of observed values for the at least one operating condition, a respective observed temperature of each semiconductor switch in the plurality of semiconductor switches within the operating semiconductor device. In an example, such measurements are received at an electronic device monitoring processor 310 from a controller such as controller 130 or controller 222, after receiving such measurements from temperature sensors installed in association with each semiconductor switch.

The baseline temperature function determination process 500 determines, at 506, a set of baseline semiconductor switch temperature values as a function of values of the at least one electrical characteristic of the operating semiconductor device. Such a function is able to be determined by any suitable technique. In some examples a function is determined such as by using a linear regression model. In some examples, the function is based on look up tables that retrieve a value of semiconductor switch temperature that is associated with stored operating condition values that are closest to provided operating condition values. In some examples, determining a baseline temperature value using any of the above options is an example of determining the baseline temperature of semiconductor switches based on the baseline semiconductor switch temperature function evaluated at the measurements of values of at least one operating condition value of the particular operating electronic device.

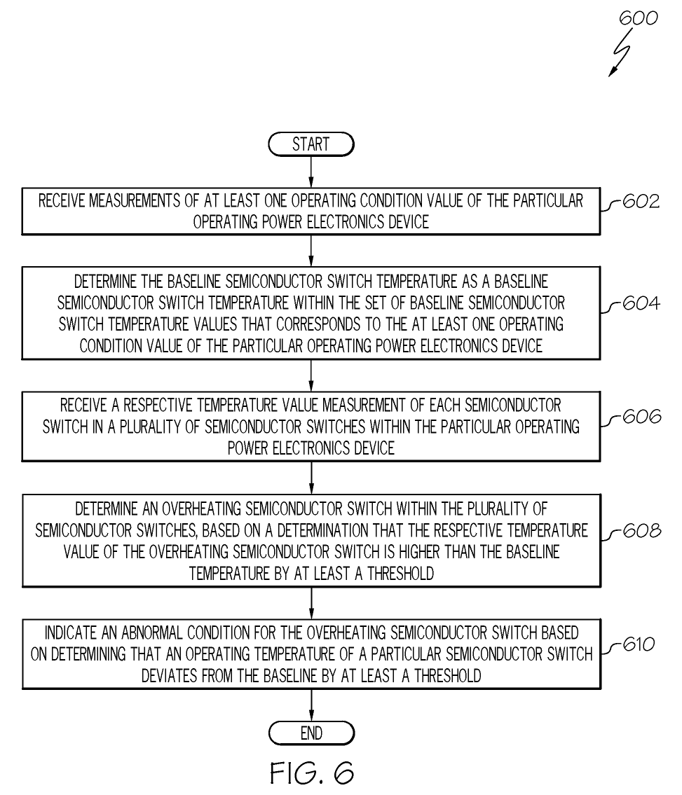

FIG. 6 illustrates an inter-device abnormality detection process 600, according to an example. The inter-device abnormality detection process 600 is an example of a process performed by the above described processor 320 when executing the inter device switch temperature baseline calculator 342. The inter-device abnormality detection process 600 is able to process semiconductor switch temperature observations under various operating condition values that are made on different electronic power devices than the electronic power device for which semiconductor switches are being monitored in order to identify overheating semiconductor switches in the electronic device being monitored. It is to be understood that the inter-device abnormality detection process 600 is also able to process semiconductor switch temperature data from a single electronic power device to determine anomalous conditions such as overheating semiconductor switches to determine a likely upcoming semiconductor switch failure.

In some examples, the inter-device abnormality detection process 600 is able to determine baseline semiconductor switch temperatures to be used for one model of electronic device based on measurements accumulated from a number of power electronic devices that have different designs such that the measured temperatures of semiconductor switches with different values of operating conditions in the power electronics devices having those different designs are accumulated as described below. In a further example, the inter-device abnormality detection process 600 is able to determine baseline semiconductor switch temperatures to be used for one model of electronic device based on measurements accumulated from a number of power electronic devices that are of the same model such that they are of a single model.

The inter-device abnormality detection process 600 receives, at 602, at least one measurement of at least one value associated with an operating condition of the particular operating electronic power device. In an example, such measurements are received at an electronic device monitoring processor 310 from a controller, such as controller 222, after receiving such measurements from monitors, such as meter 204 or ambient temperature sensor 324. In some examples, such measurements of observed values are able to be measured by, and sent from, any suitable equipment.

The inter-device abnormality detection process 600 determines, at 604, the baseline semiconductor switch temperature as a baseline semiconductor switch temperature within the set of baseline semiconductor switch temperature values that corresponds to the at least one operating condition value of the particular operating electronic power device. As described above, a baseline temperature function, which is an example of a baseline semiconductor switch temperature function, is able to be determined, such as by the above described baseline temperature function determination process 500, and that function is used in an example to determine the baseline semiconductor switch temperature for the received operating condition values. In an example, a baseline temperature of semiconductor switches is determined based on a baseline semiconductor switch temperature function evaluated at the measurements of values of at least one operating condition value of the particular operating electronic device.

The inter-device abnormality detection process 600 receives, at 606, a respective temperature value measurement of each semiconductor switch in a plurality of semiconductor switches within the particular operating electronic power device. In an example, such measurements are received at an electronic device monitoring processor 310 from a controller such as controller 130 or controller 222, after receiving such measurements from temperature sensors installed in association with each semiconductor switch.

The inter-device abnormality detection process 600 determines, at 608, an overheating semiconductor switch within the plurality of semiconductor switches, based on a determination that the respective temperature value of the overheating semiconductor switch is higher than the baseline temperature by at least a threshold. An abnormal condition for the overheating semiconductor switch is indicated, at 610, based on determining that an operating temperature of a particular semiconductor switch deviates from the baseline by at least a threshold. The inter-device abnormality detection process 600 then ends.

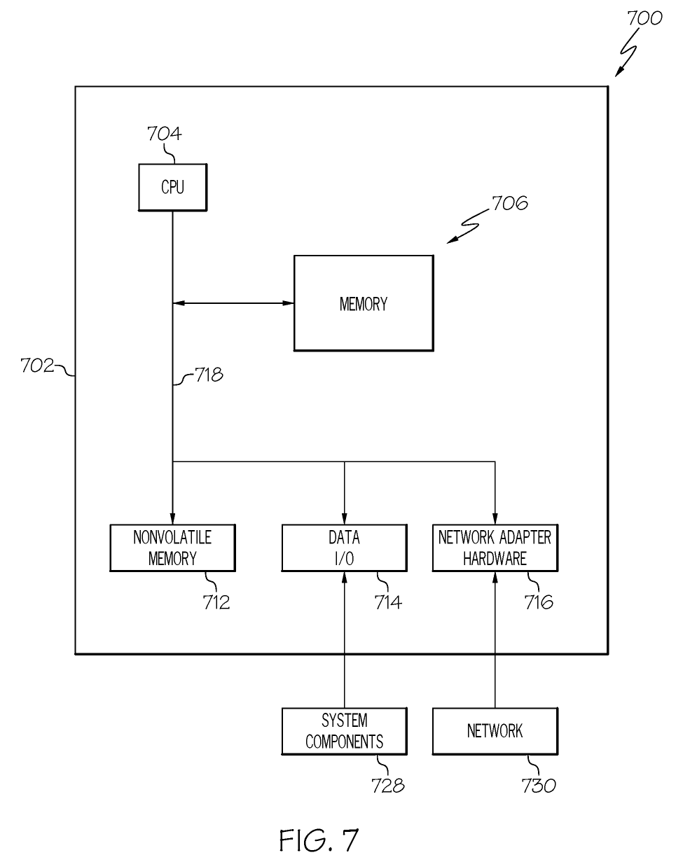

FIG. 7 illustrates a block diagram illustrating a processor 700 according to an example. The processor 700 is an example of a processing subsystem that is able to perform any of the above described processing operations, control operations, other operations, or combinations of these.

The processor 700 in this example includes a CPU 704 that is communicatively connected to a main memory 706 (e.g., volatile memory), a non-volatile memory 712 to support processing operations. The CPU is further communicatively coupled to a network adapter hardware 716 to support input and output communications with external computing systems such as through the illustrated network 730.

The processor 700 further includes a data input/output (I/O) processor 714 that is able to be adapted to communicate with any type of equipment, such as the illustrated system components 728. The data input/output (I/O) processor in various examples is able to be configured to support any type of data communications connections including present day analog and/or digital techniques or via a future communications mechanism. A system bus 718 interconnects these system components.

### Information Processing System

The present subject matter can be realized in hardware, software, or a combination of hardware and software. A system can be realized in a centralized fashion in one computer system, or in a distributed fashion where different elements are spread across several interconnected computer systems. Any kind of computer system - or other apparatus adapted for carrying out the methods described herein - is suitable. A typical combination of hardware and software could be a general purpose computer system with a computer program that, when being loaded and executed, controls the computer system such that it carries out the methods described herein.

The present subject matter can also be embedded in a computer program product, which comprises all the features enabling the implementation of the methods described herein, and which - when loaded in a computer system - is able to carry out these methods. Computer program in the present context means any expression, in any language, code or notation, of a set of instructions intended to cause a system having an information processing capability to perform a particular function either directly or after either or both of the following a) conversion to another language, code or, notation; and b) reproduction in a different material form.

Each computer system may include, inter alia, one or more computers and at least a computer readable medium allowing a computer to read data, instructions, messages or message packets, and other computer readable information from the computer readable medium. The computer readable medium may include computer readable storage medium embodying non-volatile memory, such as read-only memory (ROM), flash memory, disk drive memory, CD-ROM, and other permanent storage. Additionally, a computer medium may include volatile storage such as RAM, buffers, cache memory, and network circuits. Furthermore, the computer readable medium may comprise computer readable information in a transitory state medium such as a network link and/or a network interface, including a wired network or a wireless network, that allow a computer to read such computer readable information. In general, the computer readable medium embodies a computer program product as a computer readable storage medium that embodies computer readable program code with instructions to control a machine to perform the above described methods and realize the above described systems.

### Non-Limiting Examples

Although specific embodiments of the subject matter have been disclosed, those having ordinary skill in the art will understand that changes can be made to the specific embodiments without departing from the spirit and scope of the disclosed subject matter. The scope of the disclosure is not to be restricted, therefore, to the specific embodiments, and it is intended that the appended claims cover any and all such applications, modifications, and embodiments within the scope of the present disclosure.

What is claimed is:

1. A method of determining an abnormality of a semiconductor switch, the method comprising:
determining, based on measured temperatures of semiconductor switches within at least one operating electronic device, a baseline temperature of semiconductor switches within a particular operating electronic device;
receiving measurements of a respective temperature value of each semiconductor switch in a plurality of semiconductor switches within the particular operating electronic device;
determining an overheating semiconductor switch within the plurality of semiconductor switches, based on a determination that the respective temperature value of the overheating semiconductor switch is higher than the baseline temperature by at least a threshold; and
indicating an abnormal condition for the overheating semiconductor switch based on determining that an operating temperature of a particular semiconductor switch deviates from the baseline by at least a threshold.

2. The method of claim 1, wherein determining the baseline temperature of semiconductor switches within the particular operating electronic device comprises determining the baseline temperature based on the respective temperature value of each semiconductor switch in a plurality of semiconductor switches within the particular operating electronic device.

3. The method of claim 2 wherein the respective temperature value of each semiconductor switch in a plurality of semiconductor switches within the particular operating electronic device are measured within a defined time duration.

4. The method of claim 1, further comprising:
receiving a number of measurements of observed values of at least one operating condition of at least one electrical device containing a plurality of operating semiconductor switches;
receiving measurements, in association with each value in the number of observed values for the at least one operating condition, of a respective observed temperature of each semiconductor switch in the plurality of semiconductor switches within the operating electronic device, and
determining a baseline semiconductor switch temperature function as a function of values of the at least one operating condition of the operating electronic device,
wherein determining the baseline temperature of the semiconductor switches in a plurality of semiconductor switches within the particular operating electronic device operating comprises:
receiving measurements of values of at least one operating condition value of the particular operating electronic device; and
determining the baseline temperature of semiconductor switches based on the baseline semiconductor switch temperature function evaluated at the measurements of values of at least one operating condition value of the particular operating electronic device.

5. The method of claim 4, wherein the at least one operating condition comprises:
line voltages feeding the particular operating electronic device;
electrical current flowing through the particular operating electronic device;
electrical power factor of power flowing through the particular operating electronic device; or
ambient temperature of the particular operating electronic device.

6. The method of claim 4, wherein the at least one electrical device comprises a plurality of power electronic devices of a single model.

7. The method of claim 4, wherein the at least one electrical device comprise a plurality of power electronic devices that have different designs.

8. A system for determining an abnormality of a semiconductor switch, the system comprising:
a processor;
a memory communicatively coupled to the processor;
a baseline temperature calculator, communicatively coupled to the processor and the memory, the baseline temperature calculator configured to, when operating:
determine, based on measured temperatures of semiconductor switches within at least one operating electronic device, a baseline temperature of semiconductor switches within a particular operating electronic device; and
a semiconductor switch abnormality detector, communicatively coupled to the processor, the memory, and the baseline temperature calculator, the semiconductor switch abnormality detector configure to, when operating:
receiving measurements of a respective temperature value of each semiconductor switch in a plurality of semiconductor switches within the particular operating electronic device;
determine an overheating semiconductor switch within the plurality of semiconductor switches, based on a determination that the respective temperature value of the overheating semiconductor switch is higher than the baseline temperature by at least a threshold; and
indicate an abnormal condition for the overheating semiconductor switch based on determining that an operating temperature of a particular semiconductor switch deviates from the baseline by at least a threshold.

9. The system of claim 8, wherein the baseline temperature calculator is configured to, when operating, determine the baseline temperature of semiconductor switches within the particular operating electronic device by at least determining the baseline temperature based on the respective temperature value of each semiconductor switch in a plurality of semiconductor switches within the particular operating electronic device.

10. The system of claim 9 wherein the respective temperature value of each semiconductor switch in a plurality of semiconductor switches within the particular operating electronic device are measured within a defined time duration.

11. The system of claim 8, wherein the baseline temperature calculator is further configured to, when operating:
receive a number of measurements of observed values of at least one operating condition of at least one electrical device containing a plurality of operating semiconductor switches;
receive measurements, in association with each value in the number of observed values for the at least one operating condition, of a respective observed temperature of each semiconductor switch in the plurality of semiconductor switches within the operating electronic device, and
determine a baseline semiconductor switch temperature function as a function of values of the at least one operating condition of the operating electronic device,
wherein the baseline temperature calculator is configured to, when operating, determine the baseline temperature of the semiconductor switches in a plurality of semiconductor switches within the particular operating electronic device operating by at least:
receiving measurements of values of at least one operating condition value of the particular operating electronic device; and
determining the baseline temperature of semiconductor switches based on the baseline semiconductor switch temperature function evaluated at the measurements of values of at least one operating condition value of the particular operating electronic device.

12. The system of claim 8, wherein the at least one operating condition comprises:
line voltages feeding the particular operating electronic device;
electrical current flowing through the particular operating electronic device;
electrical power factor of power flowing through the particular operating electronic device; or
ambient temperature of the particular operating electronic device.

13. The system of claim 11, wherein the at least one electrical device comprises a plurality of power electronic devices of a single model.

14. The system of claim 11, wherein the at least one electrical device comprise a plurality of power electronic devices that have different designs.

15. A computer program product for determining an abnormality of a semiconductor switch, the computer program product comprising:
a non-transitory computer readable storage medium having computer readable program code embodied therewith, the computer readable program code comprising instructions for:
determining, based on measured temperatures of semiconductor switches within at least one operating electronic device, a baseline temperature of semiconductor switches within a particular operating electronic device;
receiving measurements of a respective temperature value of each semiconductor switch in a plurality of semiconductor switches within the particular operating electronic device;
determining an overheating semiconductor switch within the plurality of semiconductor switches, based on a determination that the respective temperature value of the overheating semiconductor switch is higher than the baseline temperature by at least a threshold; and
indicating an abnormal condition for the overheating semiconductor switch based on determining that an operating temperature of a particular semiconductor switch deviates from the baseline by at least a threshold.

16. The computer program product of claim 15, wherein determining the baseline temperature of semiconductor switches within the particular operating electronic device comprises determining the baseline temperature based on the respective temperature value of each semiconductor switch in a plurality of semiconductor switches within the particular operating electronic device.

17. The computer program product of claim 16 wherein the respective temperature value of each semiconductor switch in a plurality of semiconductor switches within the particular operating electronic device are measured within a defined time duration.

18. The computer program product of claim 15, wherein the computer readable program code further comprises instruction for:
receiving a number of measurements of observed values of at least one operating condition of at least one electrical device containing a plurality of operating semiconductor switches;
receiving measurements, in association with each value in the number of observed values for the at least one operating condition, of a respective observed temperature of each semiconductor switch in the plurality of semiconductor switches within the operating electronic device, and
determining a baseline semiconductor switch temperature function as a function of values of the at least one operating condition of the operating electronic device,
wherein the instructions for determining the baseline temperature of the semiconductor switches in a plurality of semiconductor switches within the particular operating electronic device operating comprises instructions for:
receiving measurements of values of at least one operating condition value of the particular operating electronic device; and
determining the baseline temperature of semiconductor switches based on the baseline semiconductor switch temperature function evaluated at the measurements of values of at least one operating condition value of the particular operating electronic device.

19. The computer program product of claim 18, wherein the at least one operating condition comprises:
line voltages feeding the particular operating electronic device;
electrical current flowing through the particular operating electronic device;
electrical power factor of power flowing through the particular operating electronic device; or
ambient temperature of the particular operating electronic device.

20. The computer program product of claim 18, wherein the at least one electrical device comprises one of:
a plurality of power electronic devices of a single model; or
a plurality of power electronic devices that have different designs.
